(19) United States
(12) Patent Application Publication
(10) Pub. No.: US 2026/0344324 A1
(43) Pub. Date: Oct. 29, 2026

(54) HIGH-PRESSURE WAFER PROCESSING SYSTEMS

(71) Applicant: Applied Materials, Inc., Santa Clara, CA (US)

(72) Inventors: Adib KHAN, Santa Clara, CA (US); Dmitry LUBOMIRSKY, Cupertino, CA (US); Qiwei LIANG, Fremont, CA (US); Sultan MALIK, Sacramento, CA (US); Hyun Joo LEE, Santa Clara, CA (US); Bryan M. KUAN, Santa Clara, CA (US); Justin GAU, Santa Clara, CA (US)

(21) Appl. No.: 19/189,077

(22) Filed: Apr. 24, 2025

(51) Int. Cl. H10P 72/00

(52) U.S. Cl. CPC H10P 72/0402; H10P 72/0454

(57) ABSTRACT

A high-pressure processing system for processing a substrate includes a first chamber having a support to hold a substrate during processing and a plurality of seals for maintaining the first chamber fluid tight. The high-pressure processing system includes a second chamber. A gas delivery system is configured to pressurize and depressurize the first chamber. The gas delivery system has a chamber vent line coupled to the first chamber. A sensor is disposed in fluid communication with the chamber vent line. A plurality of orifices coupled to the chamber vent line. The plurality of orifices include at least three different sized openings for varying a fluid conductance of the chamber vent line.

### TECHNICAL FIELD

This specification relates to wafer processing systems and related methods. In particular, this specification relates to methods and apparatuses for depressurizing high-pressure processing chambers.

### BACKGROUND

Micro-electronic circuits and other micro-scale devices are generally manufactured from a substrate or wafer, such as a silicon or other semiconductor material wafer. Multiple metal layers are applied onto the substrate to form micro-electronic or other micro-scale components or to provide electrical interconnects. These metal layers, e.g., copper, are plated onto the substrate, and form the components and interconnects in a sequence of photolithographic, plating, etching, polishing or other steps.

To achieve desired material properties, the substrate is typically put through an annealing process in which the substrate is quickly heated, usually to about 200-500°C and more typically to about 300-400° C. The substrate may be held at these temperatures for a relatively short time, e.g., 60-300 seconds. The substrate is then rapidly cooled, with the entire process usually taking only a few minutes. Annealing may be used to change the material properties of the layers on the substrate. It may also be used to activate dopants, drive dopants between films on the substrate, change film-to-film or film-to-substrate interfaces, densify deposited films, or to repair damage from ion implantation.

Some defects can result from incomplete thermal, or other processing, across regions of a substrate. High-pressure processing can improve consistency of processing across the substrate. In particular, annealing or deposition can occur in the high-pressure environment; this can help improve thoroughness of processing of the layer of material. As a result, the layer can be more uniformly formed or modified across the substrate. High-pressure processing can also enable chemical reactions that are not achievable at lower pressures.

However, certain materials, such as copper, will rapidly oxidize when exposed to oxygen, at temperatures over about 70° C. If the copper or other material oxidizes, the substrate may no longer be useable, or the oxide layer must first be removed before further processing. These are both unacceptable options for efficient manufacturing. Accordingly, a design factor is to isolate the substrate from oxygen when the substrate temperature is over about 70° C. Since oxygen is of course present in ambient air, avoiding oxidation of copper during annealing also can present engineering challenges. The substrate therefore may be transferred between high-pressure environments of up to 50 ATM or more than 700 PSI of a high-pressure processing chamber and low-pressure, e.g., near-vacuum, environments of different processing chambers to avoid contamination and oxidation of the substrate.

When the substrate is moved from a high-pressure environment to a near vacuum environment, the high-pressure chamber in which the substrate is processed may go through many cycles of pressurization and depressurization, where cycle times significantly impact substrate throughput. If depressurization rates are too fast, O-ring failure may occur which can bring production to a halt.

Therefore, there is a need for high-pressure chambers that allow improved pressurization and depressurization times.

### SUMMARY

In one embodiment a high-pressure processing system for processing a substrate is disclosed. The high-pressure processing system includes a first chamber having a support to hold a substrate during processing and a plurality of seals for maintaining the first chamber fluid tight. The high-pressure processing system includes a second chamber. A gas delivery system is configured to pressurize and depressurize the first chamber. The gas delivery system has a chamber vent line coupled to the first chamber. A sensor is disposed in fluid communication with the chamber vent line. A plurality of orifices coupled to the chamber vent line. The plurality of orifices include at least three different sized openings for varying a fluid conductance of the chamber vent line.

In another embodiment a method for operating a processing system is disclosed. The method begins by processing a substrate on a pedestal in a high-pressure processing environment of a first chamber. The first chamber is fluidly coupled via a slit valve assembly to a low-pressure environment of a second chamber. The first chamber is depressurized to equalize a pressure of the first chamber with a pressure of the second chamber. The depressurizing the first chamber includes switching a chamber vent line of the first chamber at a first pressure to a first orifice. The chamber vent line of the first chamber is switch at a second pressure to a second orifice. The second orifice is larger than the first orifice. The chamber vent line of the first chamber is switched at a third pressure to a third orifice. The third orifice is larger than the second orifice.

In yet another embodiment a semiconductor fabrication platform is disclosed. The semiconductor fabrication platform includes a controller configured to operate the semiconductor fabrication platform. The semiconductor fabrication platform additionally includes a central transfer chamber, a load lock chamber coupled with the central transfer chamber, a low-pressure processing system coupled with the central transfer chamber; and a high-pressure processing system coupled with the central transfer chamber. The high-pressure processing system includes a first chamber having a support to hold a substrate during processing and a plurality of seals for maintaining the first chamber fluid tight. The high-pressure processing system includes a second chamber. A gas delivery system is configured to pressurize and depressurize the first chamber. The gas delivery system has a chamber vent line coupled to the first chamber. A sensor is disposed in fluid communication with the chamber vent line. A plurality of orifices coupled to the chamber vent line. The plurality of orifices include at least three different sized openings for varying a fluid conductance of the chamber vent line.

### BRIEF DESCRIPTION OF THE DRAWINGS

FIG. 1 is a diagram of a semiconductor fabrication platform.

FIG. 2 is a diagram of a high-pressure system.

FIG. 3 is a schematic side view of an example of a high-pressure processing system.

FIG. 4 is a schematic view for a decompression system of the high-pressure processing system.

FIG. 5A illustrates a graph depicting the pressure over time for the high-pressure processing chamber under a staged orifice depressurization.

FIG. 5B illustrates a graph depicting the staged orifice depressurization rate over time for the high-pressure processing chamber.

FIG. 6 illustrates a method for depressurizing the high-pressure processing system.

### DETAILED DESCRIPTION

A semiconductor fabrication platform may include a central vacuum chamber having a robot positioned therein, a factory interface module coupled to the central vacuum chamber, a low-pressure substrate processing system coupled to the central vacuum chamber by a first vacuum valve, and a high-pressure processing system.

The high-pressure processing system for processing a substrate includes a first chamber, a pedestal positioned within the first chamber to support the substrate, a second chamber adjacent the first chamber, a vacuum processing system configured to lower a pressure within the second chamber to near vacuum, a valve assembly between the first chamber and the second chamber to isolate the pressure within the first chamber from the pressure within the second chamber, a gas delivery system configured to introduce a processing gas into the first chamber and to increase the pressure within the first chamber to above atmospheric pressure, such as up to about 50 atmospheres, while the processing gas is in the first chamber and while the first chamber is isolated from the second chamber, and a controller. The high-pressure processing system has a plurality of seals for maintaining the pressure inside the high-pressure processing system. The controller is configured to operate the gas delivery system to introduce the gas for pressuring the first chamber and to remove the gas for depressurizing the first chamber.

After introducing the processing gas and before transferring the substrate, the processing gas is exhausted by the gas delivery system from the first chamber to reduce the pressure within the first chamber. The gas delivery system is configured to maintain a decompression rate below a threshold to prevent damage to the seals in the high-pressure processing system. Advantageously, the gas delivery system reduces the instances of seal damage, thus reducing the frequency a leaks in the high-pressure processing system. As a result, fewer defects may occur during the substrate processing, and the mean time between chamber maintenance is extended.

The details of one or more implementations of the subject matter described in this specification are set forth in the accompanying drawings and the description below. Other potential features, aspects, and advantages will become apparent from the description, the drawings, and the claims.

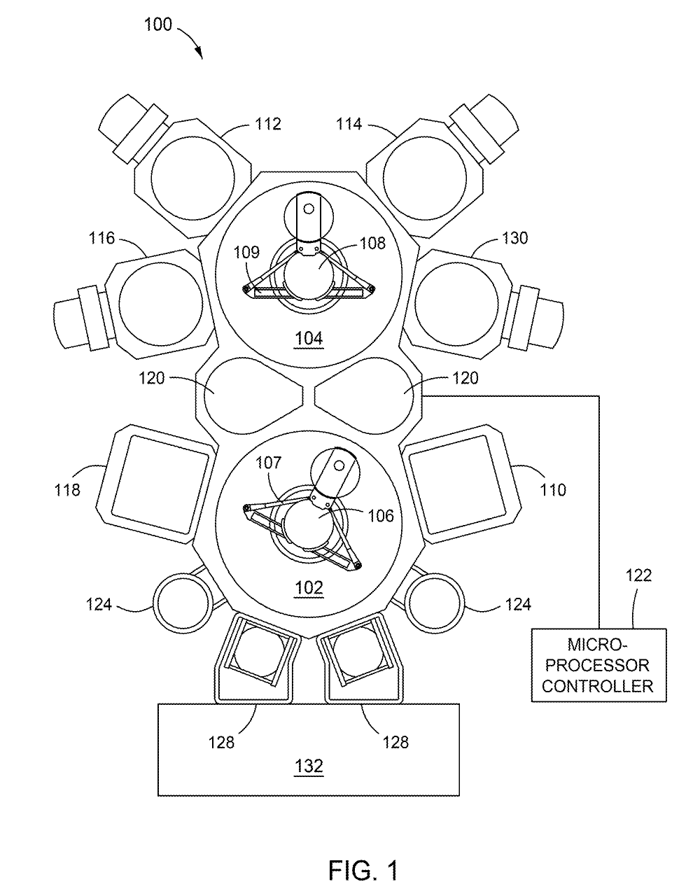

FIG. 1 shows an integrated semiconductor fabrication system 100 suitable for performing at least one embodiment of a physical vapor deposition process, a chemical vapor deposition process, and/or an annealing process described herein. In general, the semiconductor fabrication system 100 includes at least one high-pressure processing chamber, e.g., a chamber able to operate at pressures exceeding 10 atmospheres such as 50 atmospheres, to perform a high-pressure process such as deposition or annealing, and at least one low-pressure processing chamber, e.g., a chamber able to operate a pressures below about 100 milliTorr, to perform a low-pressure process such as etching, deposition, or thermal treatment. In some implementations, the semiconductor fabrication system 100 is a cluster tool having a central transfer chamber that is at low-pressure and from which multiple processing chambers can be accessed.

Some embodiments of the processes and systems described herein relate to forming layers of material, e.g., metal and metal silicide barriers, for feature definitions. For example, a first metal layer is deposited on a silicon substrate and annealed to form a metal silicide layer. A second metal layer is then deposited on the metal silicide layer to fill the feature. The annealing process to form the metal silicide layer may be performed in multiple annealing steps.

The semiconductor fabrication system 100 including a first and a second transfer chamber 102, 104, transfer robots 106, 108 positioned in the first and second transfer chambers 102, 104, respectfully, and processing chambers 110, 112, 114, 116, 118, disposed on the first and second transfer chambers 102, 104. The first and second transfer chambers 102, 104 are central vacuum chambers that interface with adjacent processing chambers 110, 112, 114, 116, 118. The first transfer chamber 102 and the second transfer chamber 104 are separated by pass-through chambers 120, which may comprise cool down or pre-heating chambers. The pass-through chambers 120 also may be pumped down or ventilated during substrate handling when the first transfer chamber 102 and the second transfer chamber 104 operate at different pressures. For example, the first transfer chamber 102 may operate between about 100 milliTorr and about 5 Torr, such as about 40 milliTorr, and the second transfer chamber 104 may operate between about 1×10−5 Torr and about 1×10−8 Torr, such as about 1×10−7 Torr.

The operations of the semiconductor fabrication system 100 are controlled by a controller 122. The controller 122 can operate individual operations for each of the chambers of the semiconductor fabrication system 100 to process the substrate.

The first transfer chamber 102 is coupled with two degas chambers 124, two load lock chambers 128, a reactive pre-clean chamber 118, at least one physical vapor deposition chamber, preferably a long throw physical vapor deposition (PVD) chamber 110, and the pass-through chambers 120. The pre-clean chamber may be a PreClean II chamber, commercially available from Applied Materials, of Santa Clara, California. Substrates (not shown) are loaded into the semiconductor fabrication system 100 through load lock chambers 128. For example, a factory interface module 132, if present, would be responsible for receiving one or more substrates, e.g., wafers, cassettes of wafers, or enclosed pods of wafers, from either a human operator or an automated substrate handling system. The factory interface module 132 can open the cassettes or pods of substrates, if applicable, and move the substrates to and from the load lock chambers 128. The processing chambers 110, 112, 114, 116, 118 receive the substrates from the first and second transfer chambers 102, 104, process the substrates, and allow the substrates to be transferred back into the first and second transfer chambers 102, 104. After being loaded into the semiconductor fabrication system 100, the substrates are sequentially degassed and cleaned in degas chambers 124 and the pre-clean chamber 118, respectively.

Each of the processing chambers are isolated from the first and second transfer chambers 102, 104 by an slit valve which allows the processing chambers to operate at a different level of vacuum than the first and second transfer chambers 102, 104 and prevents any gasses being used in the processing chamber from being introduced into the transfer chamber. The load lock chambers 128 are also isolated from the first and second transfer chambers 102, 104 with slit valves. Each load lock chamber 128 has a door which opens to the atmospheric environment of the factory interface module 132. In normal operation, a substrate is placed into the load lock chamber 128 through the door from the factory interface module 132 and the door is closed. The load lock chamber 128 is then evacuated to the same pressure as the first transfer chamber 102 and the slit valve between the load lock chamber 128 and the first transfer chamber 102 is opened. The robot in the first transfer chamber 102 is moved into position and the substrate is removed from the load lock chamber 128.

The transfer robot 106 in the first transfer chamber 102 then rotates with the substrate so that the substrate is aligned with a processing chamber position. The processing chamber is flushed of any toxic gasses, brought to the same pressure level as the transfer chamber, and the slit valve is opened. The transfer robot 106 then moves the wafer into the processing chamber where it is lifted off the robot. The transfer robot 106 is then retracted from the processing chamber and the slit valve is closed. The processing chamber then goes through a series of operations to execute a specified process on the wafer. When complete, the processing chamber is brought back to the same environment as the first transfer chamber 102 and the slit valve is opened. The transfer robot 106 removes the wafer from the processing chamber and then either moves it to another processing chamber for another operation or replaces it in the load lock chamber 128 to be removed from the semiconductor fabrication system 100 when the entire cassette of wafers has been processed.

The transfer robots 106, 108 include robot arms 107, 109, respectively, that support and move the substrate between different processing chambers. The transfer robot 106 moves the substrate between the degas chambers 124 and the pre-clean chamber 118. The substrate may then be transferred to the long throw PVD chamber 110 for deposition of a material thereon.

The second transfer chamber 104 is coupled to a cluster of processing chambers 110, 112, 114, 130. The processing chambers 110, 112 may be chemical vapor deposition (CVD) chambers for depositing materials, such as tungsten, as desired by the operator. An example of a suitable CVD chamber includes W×Z™ chambers, commercially available from Applied Materials, Inc., located in Santa Clara, Calif. The CVD chambers are preferably adapted to deposit materials by atomic layer deposition (ALD) techniques as well as by conventional chemical vapor deposition techniques. The processing chambers 114 and 130 may be Rapid Thermal Annealing (RTA) chambers, or Rapid Thermal Process (RTP) chambers, that can anneal substrates at vacuum or near vacuum pressures. An example of a RTA chamber 114 is a RADIANCE™ chamber, commercially available from Applied Materials, Inc., Santa Clara, Calif. Alternatively, the processing chambers 114 and 130 may be W×Z™ deposition chambers capable of performing high temperature CVD deposition, annealing processes, or in situ deposition and annealing processes. The PVD processed substrates are moved from the first transfer chamber 102 into the second transfer chamber 104 via the pass-through chambers 120. Thereafter, the transfer robot 108 moves the substrates between one or more of the processing chambers 110, 112, 114, 130 for material deposition and annealing as required for processing.

RTA chambers (not shown) may also be disposed on the first transfer chamber 102 of the semiconductor fabrication system 100 to provide post deposition annealing processes prior to substrate removal from the semiconductor fabrication system 100 or transfer to the second transfer chamber 104.

While not shown, a plurality of vacuum pumps is disposed in fluid communication with each transfer chamber and each of the processing chambers to independently regulate pressures in the respective chambers. The pumps may establish a vacuum gradient of increasing pressure across the apparatus from the load lock chamber to the processing chambers.

Alternatively or in addition, a plasma etch chamber, such as a Decoupled Plasma Source chamber (DPS™ chamber) manufactured by Applied Materials, Inc., of Santa Clara, Calif., may be coupled to the semiconductor fabrication system 100 or in a separate processing system for etching the substrate surface to remove unreacted metal after PVD metal deposition and/or annealing of the deposited metal. For example, in forming cobalt silicide from cobalt and silicon material by an annealing process, the etch chamber may be used to remove unreacted cobalt material from the substrate surface.

Other etch processes and apparatus, such as a wet etch chamber, can be used in conjunction with the process and apparatus described herein.

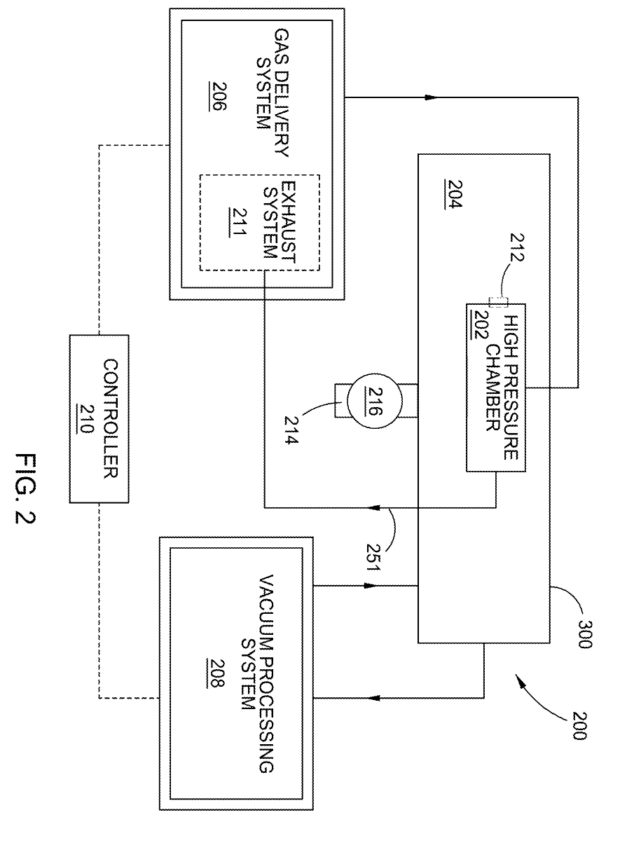

FIG. 2 illustrates a controlled high-pressure system 200 that creates a high-pressure environment for processing a substrate and a low-pressure environment for the substrate when the substrate is being transferred between processing chambers. The controlled high-pressure system 200 includes a first chamber 202 suitable for high-pressure processing and a second chamber 204 at vacuum. The first chamber 202 can correspond to one of the processing chambers 110, 112, 114, 116, 118, 130 of the semiconductor fabrication system 100, and the second chamber 204 can correspond to one of the first and second transfer chambers 102, 104 of the semiconductor fabrication system 100. Alternatively, in some implementations, one of the processing chambers 110, 112, 114, 116, 118, 130 includes both the first chamber 202 and the second chamber 204. The first chamber 202 corresponds to an inner chamber, and the second chamber 204 corresponds to an outer chamber surrounding the inner chamber collectively referred to as a high-pressure processing chamber 300.

The second chamber 204 may have an interior volume. The first chamber 202 may be disposed in the interior volume of the second chamber 204. In one example, the interior volume of the second chamber 204 contains at least a portion of the first chamber 202. For example, the slit valve assembly for the first chamber 202 may be disposed in the interior volume of the second chamber 204. The slit opening of the first chamber 202 aligns with and is spaced apart from the slit opening of the second chamber 204. The alignment of the slit openings in the first and second chambers 202/204 allows for a substrate to be transferred through the second chamber 204 into the first chamber 202. In one example, the slit openings of the first and second chambers 202/204 are of such proximity to each other that the substrate cannot fully enter the second chamber 204 without beginning to enter the first chamber 202. That is, a substrate is wider than the distance between the slit openings of the first and second chambers 202/204. It should be appreciated that the second chamber 204 may be coupled to the transfer chamber and the first chamber 202 is coupled to the transfer chamber by way through the second chamber 204. In this manner, the first chamber 202 is isolated from the transfer chamber by the second chamber 204.

The pressure within the first chamber 202 can be controlled independently of the pressure in the second chamber 204. If the first and second chambers 202, 204 are distinct from the transfer chambers, the first and second chambers 202, 204 can have pressures that are controlled independently of the pressures within the transfer chambers. The controlled high-pressure system 200 further includes a gas delivery system 206, a vacuum processing system 208, and a controller 210. In some examples, the controller 122 of the semiconductor fabrication system 100 can include or be the controller 210.

The second chamber 204 is a low-pressure chamber is adjacent to or surrounding the first chamber 202. The second chamber 204 can correspond to a transfer chamber, e.g., the first transfer chamber 102 or the second transfer chamber 104, that receives the substrate between different processing chambers. The low-pressure environment of the second chamber 204 can inhibit contamination and/or oxidation of the substrate or the material formed on the substrate.

The gas delivery system 206 is operated to pressurize and depressurize the first chamber 202. The first chamber 202 is a high-pressure processing chamber that receives a processing gas from the gas delivery system 206 and establishes a high-pressure, e.g., at a pressure of about 50 atmospheres or 700 PSI. The processing gas can interact with the layer being processed so as to anneal the layer, e.g., by modifying the layer or reacting with the material to form a new layer. The processing gas can include hydrogen, e.g., the processing gas can be hydrogen gas H₂. Alternatively, the processing gas can be a precursor gas that serves as a source for the material to be formed on the substrate, e.g., for a deposition process. To pressurize the first chamber 202, the gas delivery system 206 introduces the processing gas into the first chamber 202. In some cases, the gas delivery system 206 can also introduce steam into the first chamber 202 to increase the pressure within the first chamber 202.

The gas delivery system 206 can include an exhaust system 211 to exhaust the processing gas from a chamber exhaust line 251 of the first chamber 202, thereby depressurizing the first chamber 202. The vacuum processing system 208 has one or more vacuum pumps operable to generate a vacuum within the second chamber 204. The vacuum processing system 208 is operated to control the pressure of the second chamber 204 to be at a vacuum or near-vacuum pressure, e.g., less than 1 milliTorr. For example, the vacuum processing system 208 lowers a pressure within the second chamber 204 to near vacuum, thereby creating the appropriate low-pressure environment for transfer of the substrate.

A slit valve assembly 212 between the first chamber 202 and the second chamber 204 isolates the pressure within the first chamber 202 from the pressure within the second chamber 204. The high-pressure environment within the first chamber 202 can thus be separated and sealed from the low-pressure environment within the second chamber 204. The slit valve assembly 212 is openable to enable the substrate to be transferred from the first chamber 202 directly into the second chamber 204 or to enable the substrate to be transferred from the second chamber 204 directly into the first chamber 202.

The high-pressure system 200 includes a foreline 214 connected to a transfer chamber, e.g., one of the first and second transfer chambers 102, 104, and connected to an outside environment. An isolation valve 216 is arranged along the foreline 214 to isolate the pressure within the second chamber 204 from the pressure in the foreline 214. The isolation valve 216 can be operated to adjust the pressure within the second chamber 204 and to release gases within the second chamber 204 into the foreline 214. The isolation valve 216 can be operated in conjunction with the vacuum processing system 208 to regulate the pressure within the second chamber 204.

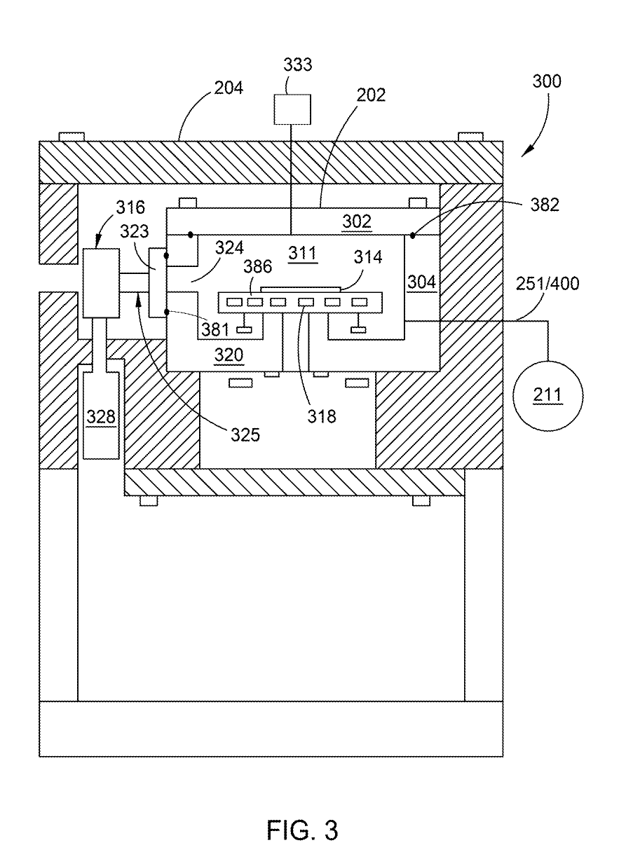

FIG. 3 illustrates a sectional view of the high-pressure processing chamber 300. The high-pressure processing chamber 300 includes the first chamber 202, a pedestal 326, the second chamber 204, and the controller 210 (shown in FIG. 2). The first chamber 202 has chamber walls 320 and a lid 302. Seals 382 may be disposed between the chamber walls 320 and lid 302 to prevent gas from moving there between. The chamber walls 320 and lid 302 enclose a processing volume 311. The pedestal 326 is disposed in the processing volume 311. A substrate 314 is supported on the pedestal 326 for processing within the first chamber 202. The gas delivery system 206 and the vacuum processing system 208 operate to maintain the low and high-pressure environments for processing the substrate 314 in the processing volume 311 of the high-pressure processing chamber 300. For example, the gas delivery system 206 provides a pressurizing gas into the processing volume 311 for producing a high-pressure in the processing volume 311 while processing the substrate. After processing the substrate, the vacuum processing system 208 removes the pressurizing gas from the processing volume 311 to a near vacuum pressure for equalizing the pressure between the first chamber 202 and the second chamber 204.

The high-pressure processing chamber 300 has the slit valve assembly 212. The slit valve assembly 212 has an arm 325 that contacts an outer surface of an chamber wall 320 defining the first chamber 202. The arm 325 cover a slit (or aperture) in the chamber wall 320. The slit valve assembly 212 operates to isolate the first chamber 202 from the second chamber 204. The slit valve assembly 212 can be positioned between the first chamber 202 and the second chamber 204. Alternately, the slit valve assembly 212 can be positioned inside the first chamber 202.

The slit valve assembly 212 includes a slit valve 323 between the first chamber 202 and the second chamber 204. The slit valve 323 is moveably coupled to an arm 325. An aperture 321extends through one of the chamber walls 320 provided the first chamber 202. An arm 325 coupled to the slit valve 323 is movable relative to the chamber walls 320 so that the slit valve 323 can be moved to a position in which it forms a seal with the chamber walls 320. The high-pressure processing chamber 300 includes an actuator 328 operable to drive the arm 325 for moving the slit valve 323. The slit valve 323 may have a seal 381 for creating an airtight seal covering the aperture 321. The slit valve 323 is movable between an open position and a closed position by the actuator 328 for fluidly sealing the first chamber 202 from the second chamber 204.

The controller 210 can operate the high-pressure processing chamber 300 to form the layer of material on or otherwise process the substrate 314 at a pressure exceeding 1 ATM. The controller 210 can operate the slit valve assembly 212 to open and close the first chamber 202 from the second chamber 204. The controller can operate the actuator 328 to drive the arm 325. The controller 210 can operate the gas delivery system 206 and exhaust system 211 for pressurizing and depressurizing the high-pressure processing chamber 300.

The high-pressure processing chamber 300 can be used for annealing, such as annealing of a metal or other material. In one example, the high-pressure processing chamber 300 is used for annealing copper or cobalt. For annealing metals, a gas source 333 may provide a processing gas. The process gas can be hydrogen gas (H₂) or deuterium gas (D₂). In another example, the high-pressure processing chamber 300 can be used for annealing an oxide, such as silicon dioxide (SiO₂), for example. For annealing oxides, the processing gas can be water vapor or steam. The high-pressure processing chamber 300 can be used for annealing of silicon-germanium material. For annealing silicon-germanium material, the processing gas can be deuterium gas (D₂). The high-pressure processing chamber 300 can be used to form a metal silicide layer from a cobalt or nickel layer film, or other materials such as titanium, tantalum, tungsten, molybdenum, platinum, iron, niobium, palladium, and combinations thereof, and other alloys including nickel cobalt alloys, cobalt tungsten alloys, cobalt nickel tungsten alloys, doped cobalt and nickel alloys, or nickel iron alloys, to form a metal silicide material. Each of the different chambers of a semiconductor fabrication system 100 can have varying pressure environments, ranging from near-vacuum to around 50 atmospheres. The slit valves, e.g., vacuum valves, and particularly the seals, in high-pressure processing chamber 300 can isolate the pressures from one another such that these varying pressure environments can be maintained within each chamber.

In the high-pressure processing chamber 300, gas may penetrate the elastomeric material of the seals 381/382. The higher the chamber pressure, the larger the quantity of gas may become trapped in the seal. Gas trapped in the seal may case high-pressure seal failure due to gas in the seal material pulling the seals apart during depressurization due to the gas expanding within the material of the seal. The expanding gas may cause the seal to blister, crack, and pit or even rupture.

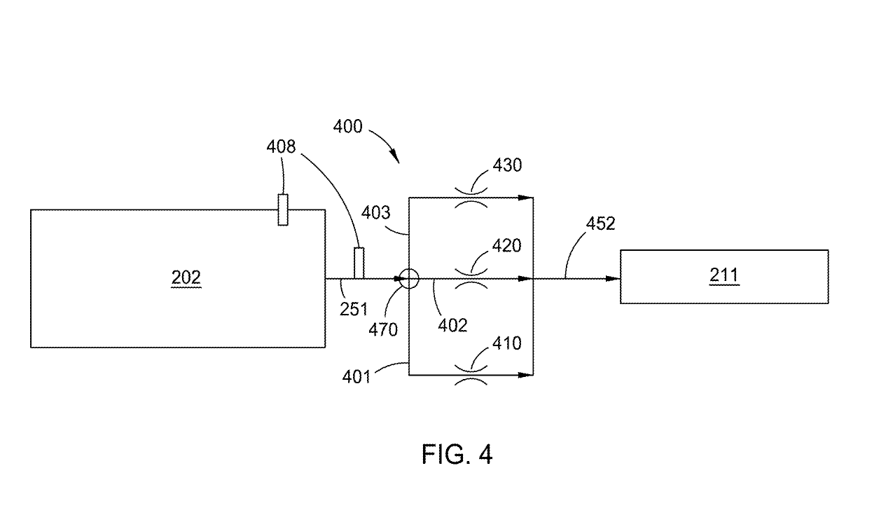

FIG. 4 is a schematic view for a decompression system 400 for the high-pressure processing chamber 300. A sensor 408 is provided in the chamber exhaust line 251 or high-pressure processing chamber 300. The sensor 408 provides feedback for controlling the decompression system 400 and thus, the rate of depressurization of the high-pressure processing chamber 300.

The decompression system 400 couples the high-pressure processing chamber 300 to the exhaust system 211. The chamber exhaust line 251 allows fluids, such as gas, from the high-pressure processing chamber 300 to flow to the decompression system 400. The exhaust system 211 has an inlet 452, which couples the decompression system 400 to the exhaust system 211.

The decompression system 400 may have one or more vent lines coupled via a switch 470 to the chamber exhaust line 251. The one or more vent lines are coupled in parallel between the switch 470 and an inlet 452 of the decompression system 400. In one example, the switch 470 may be a selector valve, or a plurality of on/off valve that are operable to determine which of the one or more vent lines receive fluid (e.g., gas) exiting the high-pressure of the first chamber 202 through the chamber exhaust line 251. In one example, the at least one or more of vent lines have a conductance different than another of one of the vent lines. The switch 470 may operate to selectively fluidly couple the chamber exhaust line 251 to a first vent line 401 having a first orifice 410. The switch 470 may additionally operate to selectively fluidly couple the chamber exhaust line 251 to a second vent line 402 having a second orifice 420. The switch 470 may additionally operate to selectively fluidly couple the chamber exhaust line 251 to a third vent line 403 having a third orifice 430. The first orifice 410, second orifice 420 and third orifice 430 may be flow restrictors, orifice plates, needle valves or other flow controller. The first orifice 410, second orifice 420 and third orifice 430 may also be a designed in difference in the flow conductance of the first vent line 401, second vent line 402 and third vent line 403. For example, the first vent line 401, second vent line 402 and third vent line 403 all may have different diameters, lengths, turns, baffles or other physical attribute that causes the conductance of the first, second and third vent lines 401, 402, 403 to be different, and thus function as the first, second and third orifice 410, 420, 430. The first orifice 410, second orifice 420 and third orifice 430 each operate to control the fluid conductance of a respective one of the first vent line 401, the second vent line 402 and the third vent line 403. For example, the first orifice 410 is smaller than the second orifice 420 to provide lower fluid conductance in the first vent line 401 compared to the second vent line 402. The second orifice 420 is smaller than the third orifice 430 to provide lower fluid conductance in the second vent line 402 compared to the third vent line 403. Thus, the fluid conductance chamber exhaust line 251 between the high-pressure of the first chamber 202 and the exhaust system 211 can be controlled by the switch 470, with the operation of the switch 470 controlled by the controller 210 based on the pressure reading provided by the sensor 408. The controller 219 may selectively route the fluid/gas from the chamber exhaust line 251 through only a single vent line, any combination of two vent lines, or all through 3 vent lines (401/402/403).

It has been discovered that the incident of seal failure can be reduced during depressurization of the high-pressure processing chamber 300 by maintaining at least a minimum -6 psi/sec maximum depressurization rate threshold. Depressurization of H₂ from the high-pressure processing chamber 300 within 6 minutes without exceeding the -6psi/sec maximum depressurization rate threshold can be reliably performed utilizing a staged depressurization method. The staged depressurization method utilizes different sized orifices for controlling the rate of depressurization. In the example shown, a plurality of orifices are coupled to the chamber vent line, wherein the plurality of orifices include at least three different sized openings for controlling the rate of a fluid flow out of the chamber vent line. In one example, three different orifice sizes are provided. However, it should be appreciated that any number of orifices can be used as long as the maximum depressurization rate threshold is not exceeded. For example, a single valve having a variable or changeable orifice size can be controlled to provide a specified orifice sized matched to the pressure in the chamber exhaust line 251.

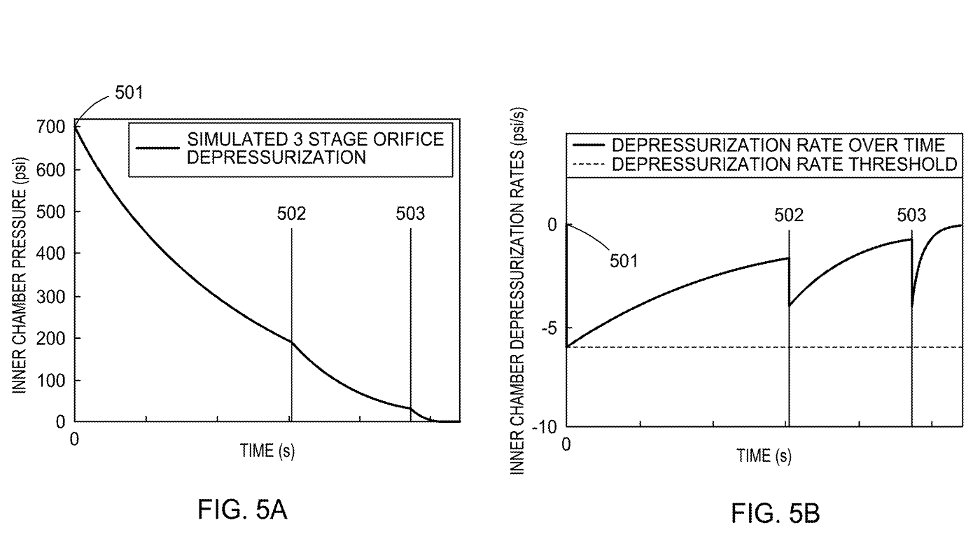

Further discussion of FIG. 4 will include information from FIGS. 5A and 5B. FIG. 5A illustrates a graph depicting the pressure over time for the high-pressure processing chamber 300 under a staged orifice depressurization of the high-pressure processing chamber 300. FIG. 5B illustrates a graph depicting the staged orifice depressurization rate over time for the high-pressure processing chamber 300.

In FIG. 5B, the high-pressure processing chamber 300 has a starting pressure of about 700 PSI and a final pressure at or near vacuum pressure. The opening diameter for each of the first orifice 410, second orifice 420 and third orifice 430 are sized based on the expected pressure in the chamber exhaust line 251 so that a rate of depressurization of the high-pressure processing chamber 300 is maintained below a threshold. In one embodiment, the maximum depressurization rate threshold is between about -8 PSI/sec and about -4 PSI/sec, such as about -6 PSI/sec. The first orifice 410 is sized for the starting pressure and may have an opening diameter sized between about 0.002” and about 0.007”. As the pressure in the high-pressure processing chamber 300 and the chamber exhaust line 251 drops, the rate of depressurization also drops. This enables the opening diameter of the orifice to be increased. In one example, the second orifice 420 is sized for a particular pressure achieved in the chamber exhaust line 251 when the depressurization rate drops below a lower depressurization rate threshold. The lower depressurization rate threshold can be maximized, i.e., having a greater rate of depressurization, to speed the time of depressurizing the high-pressure processing chamber 300. The second orifice 420 is sized for the pressure in the chamber exhaust line 251 and may have an opening diameter sized between about 0.005” and about 0.015”. Similarly, as the pressure in the chamber exhaust line 251 continues to drop, the orifice size is selected to increase the rate of depressurization at the lower pressure. For example, the third orifice 430 may be sized for the pressure in the chamber exhaust line 251 and have an opening diameter sized between about 0.010” and about 0.030”. The third orifice 430 may be the last in the sequence of orifices used to depressurize the high-pressure processing chamber 300 while maintaining the rate of depressurization below the maximum depressurization rate threshold. Alternately, the third orifice may be but one in a long line of orifices used to depressurize the high-pressure processing chamber 300. In yet other alternatives, the first orifice 410 may be adjustable in the opening diameter size and the sensor 408 in the chamber exhaust line 251 or high-pressure processing chamber 300 provides feedback for adjusting the opening diameter size for maintaining the rate of depressurization below the maximum depressurization rate threshold.

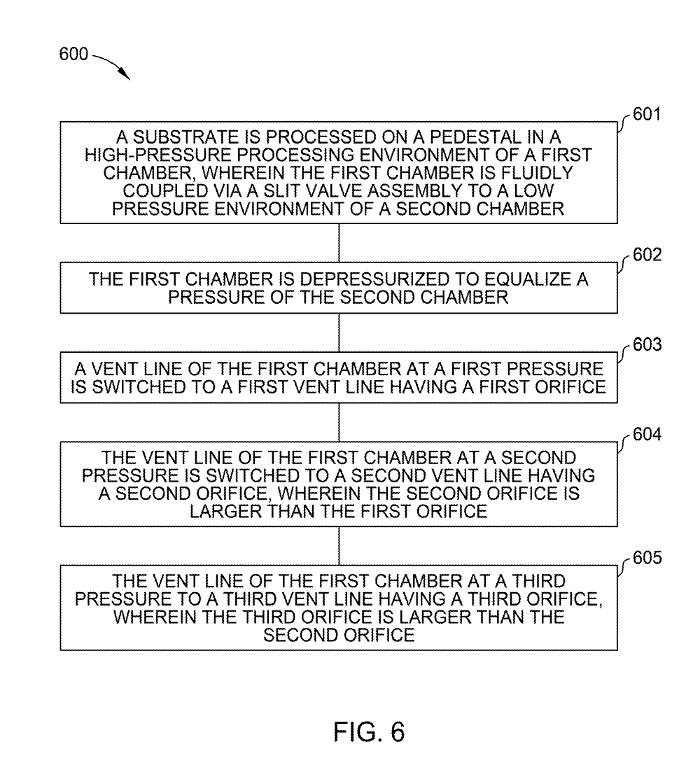

FIG. 6 illustrates a flow diagram of a method 600 for operating a high-pressure processing chamber 300, such as the high-pressure processing chamber 300, among others. The description of method 600 additionally relies on the graphs depicted in FIGS. 5A and 5B. In a first operation 601 of the method 600, a substrate is processed on a pedestal in a high-pressure processing environment of a first chamber, wherein the first chamber is fluidly coupled via a slit valve assembly to a low-pressure environment of a second chamber. The high-pressure chamber may be used for annealing, doping, etching or film deposition. For example, the high pressure may allow precursors to react for forming thin films in a chemical vapor deposition process.

In a second operation 602 of the method 600, the processing of the substrate is complete and the first chamber is readied to be depressurized for equalizing the pressure in the first chamber with a pressure of the second chamber. The first chamber may be at 700 PSI or more at the beginning of operation 602. The second chamber may be at near vacuum pressure. To ensure the seals in the first chamber do not fail, a maximum depressurization rate threshold is maintain at or below -6 PSI/sec.

In a third operation 603, occurring at a first time 501 when the chamber exhaust line 251 of the high-pressure processing chamber 300 is at first pressure, the chamber exhaust line 251 is fluidly coupled with the first orifice 410. At this time, the high-pressure processing chamber 300 may be fluidly decoupled only through the first orifice 410 to the exhaust system 211. In one embodiment, the first pressure is between about 500 PSI and about 900 PSI, such as about 700 PSI. The first orifice 410 has an opening diameter sized between about 0.002” and about 0.007”, such as about 0.005”. In one example, the first orifice 410 is on the first vent line 401 coupled by way of the switch 470 to the chamber exhaust line 251. In another example, the first orifice 410 is part of a single valve having an adjustable or changeable orifice size.

The controller may receive time based pressure information for the chamber exhaust line 251 or the high-pressure processing chamber 300. The controller may comparing the pressure at time intervals in the vent line to determiner a rate of depressurization. Based on the rate of depressurization of the high-pressure processing chamber 300, the controller sends instructions for a switch to fluidly couple the chamber exhaust line 251 of the high-pressure processing chamber 300 to one of the first orifice 410, the second orifice 420, and/or third orifice 430.

In a fourth operation 604 occurring at a second time 502 when the chamber exhaust line 251 of the high-pressure processing chamber 300 is at second pressure, the chamber exhaust line 251 is fluidly coupled to the second orifice 420. At this time, the high-pressure processing chamber 300 may be fluidly decoupled from the first orifice 410 such that the exhaust gas only goes through the second orifice 420. In one embodiment, the first pressure is between about 100 PSI and about 500 PSI, such as about 188 PSI. The second orifice 420 has an opening diameter sized between about 0.005” and about 0.015”, such as about 0.008”. In one example, the second orifice 420 is on the second vent line 402 coupled by way of the switch 470 to the chamber exhaust line 251. In another example, the second orifice 420 is part of the single valve having an adjustable or changeable orifice size.

In a third operation 603 occurring at a third time 503 when the chamber exhaust line 251 of the high-pressure processing chamber 300 is at a third pressure, the chamber exhaust line 251 is fluidly coupled to the third orifice 430. At this time, the high-pressure processing chamber 300 may be fluidly decoupled from the first orifice 410 and the second orifice 420 such that the exhaust gas only goes through the third orifice 430. In one embodiment, the first pressure is between about 20 PSI and about 100 PSI, such as about 32 PSI. The third orifice 430 has an opening diameter sized between 0.010” and about 0.030”, such as about 0.020”. It should be appreciated that the method of depressurization may include additional operations for adjusting the orifice size upward for minimizing the time to depressurize the high-pressure processing chamber 300 at a rate below the maximum depressurization threshold. In one example, the third orifice 430 is on the third vent line 403 coupled by way of the switch 470 to the chamber exhaust line 251. In another example, the third orifice 430 is part of the single valve having an adjustable or changeable orifice size.

Utilizing the operations 601 through 603, depressurization of the high-pressure processing chamber 300 can be achieved in under 6 min without exceeding a maximum depressurization rate threshold of -6 psi/sec. In one example, a depressurization time for the of the high-pressure processing chamber 300 was achieved at 4 min 34 sec without exceeding the maximum depressurization rate threshold of -6 psi/sec.

Advantageously, by routing the chamber vent flow during depressurization through a different vent line, or sized orifice, having a different conductance, the rate of pressure drop with in the high-pressure chamber can be controlled in a manner that prevents damage to the seals in the high-pressure chamber. Accordingly, other implementations are within the scope of the claims.

What is claimed is:

1. A high-pressure processing system comprising:
a first chamber having a substrate support configured to hold a substrate during processing, and a plurality of seals for maintaining the first chamber fluid tight; and
a gas delivery system configured to pressurize and depressurize the first chamber, the gas delivery system comprising:
a chamber vent line coupled to the first chamber;
a sensor disposed in fluid communication with the chamber vent line; and
a plurality of orifices coupled to the chamber vent line, wherein the plurality of orifices include at least three different sized openings for controlling the rate of a fluid flow out of the chamber vent line.

2. The high-pressure processing system of claim 1 further comprising a slit valve assembly disposed between the first chamber and the second chamber, the slit valve assembly configured to selectively isolate the first chamber from the second chamber.

3. The high-pressure processing system of claim 1, wherein the gas delivery system further comprises:
a first vent line having a first orifice of a first diameter coupled to the chamber vent line;
a second vent line having a second orifice of a second diameter coupled to the chamber vent line, wherein the second diameter is larger than the first diameter; and
a third vent line having a third orifice of a third diameter coupled to the chamber vent line, wherein the third diameter is larger than the second diameter.

4. The high-pressure processing system of claim 3, further comprising:
a switch configured to selectively couple the chamber vent line to one or a combination of two or more of the first vent line, the second vent line, and the third vent line.

5. The high-pressure processing system of claim 4, wherein the fluid conductance of the chamber vent line varies in response to a selection of a fluid path flow through the first vent line, the second vent line, or the third vent line.

6. The high-pressure processing system of claim 5, wherein the first orifice has a first diameter sized between about .002” and about 0.007”, the second orifice has a second diameter sized between about 0.005” and about 0.015” and the third orifice has a third diameter sized between about 0.010” and about 0.030”.

7. The high-pressure processing system of claim 6, further comprising:
a controller configured to operate the switch in response to a pressure sensed in the high-pressure processing system or chamber vent line.

8. The high-pressure processing system of claim 1, wherein pressurizing the first chamber comprises increasing a pressure of the first chamber to at least about 700 PSI.

9. A method for operating a processing system, the method comprises:
processing a substrate on a pedestal in a high-pressure processing environment of a first chamber, wherein the first chamber is fluidly coupled via a slit valve assembly to a low-pressure environment of a second chamber;
depressurizing the first chamber to equalize a pressure of the first chamber with a pressure of the second chamber wherein depressurizing the first chamber comprises:
switching a chamber vent line of the first chamber at a first pressure to a first orifice;
switching the chamber vent line of the first chamber at a second pressure to a second orifice, wherein the second orifice is larger than the first orifice; and
switching the chamber vent line of the first chamber at a third pressure to a third orifice, wherein the third orifice is larger than the second orifice.

10. The method of claim 9 wherein the first pressure is greater than the second pressure and the second pressure is greater than the first pressure, and wherein first orifice is smaller than the second orifice and the second orifice is smaller than the third orifice.

11. The method of claim 9 further comprising:
sensing a pressure in the chamber vent line;
comparing the pressure in the chamber vent line to determiner a depressurization rate; and
based on the depressurization rate, sensing instructions for a switch to fluidly couple the chamber vent line to one of the first orifice, second orifice, and/or third orifice.

12. The method of claim 11 wherein a maximum rate of depressurization is maintain at or below -6 PSI/sec.

13. The method of claim 11 wherein a time to depressurize the first chamber from 700 PSI to at or near vacuum is about 6 minutes.

14. The method of claim 9 wherein the first orifice is disposed on a first vent line, the second orifice is disposed on a second vent line, and the third orifice is disposed on a third vent line.

15. The method of claim 14 wherein the first vent line, the second vent line, and the third vent line are fluidly coupled to the chamber vent line via a switch and to an exhaust system at an end opposite the switch.

16. A semiconductor fabrication platform, comprising:
a controller configured to operate the semiconductor fabrication platform;
a central transfer chamber;
a load lock chamber coupled with the central transfer chamber;
a low-pressure processing system coupled with the central transfer chamber; and
a high-pressure processing system coupled with the central transfer chamber, the high-pressure processing system comprising:
a first chamber having a support to hold a substrate during processing and a plurality of seals for maintaining the first chamber fluid tight;
a second chamber; and
a gas delivery system configured to pressurize and depressurize the first chamber, the gas delivery system comprising:
a chamber vent line coupled to the first chamber;
a sensor disposed in fluid communication with the chamber vent line; and
a plurality of orifices coupled to the chamber vent line, wherein the plurality of orifices include at least three different sized openings for controlling the rate of a fluid flow out of the chamber vent line.

17. The semiconductor fabrication platform of claim 16, wherein the gas delivery system further comprises:
a first vent line having a first orifice of a first diameter coupled to the chamber vent line;
a second vent line having a second orifice of a second diameter coupled to the chamber vent line, wherein the second diameter is larger than the first diameter; and
a third vent line having a third orifice of a third diameter coupled to the chamber vent line, wherein the third diameter is larger than the second diameter.

18. The semiconductor fabrication platform of claim 17, wherein the gas delivery system further comprises:
a switch configured to selectively couple the chamber vent line to one of the first vent line, the second vent line, and the third vent line, wherein the controller is configured to operate the switch in response to a pressure sensed in the high-pressure processing system or chamber vent line.

19. The semiconductor fabrication platform of claim 18, wherein the fluid conductance of the chamber vent line varies in response to a selection of a fluid path flow through the first vent line, the second vent line, or the third vent line.

20. The semiconductor fabrication platform of claim 17, wherein the first orifice has a first diameter sized between about .002” and about 0.007”, the second orifice has a second diameter sized between about 0.005” and about 0.015” and the third orifice has a third diameter sized between about 0.010” and about 0.030”.
